(19) United States
(12) Patent Application Publication
(10) Pub. No.: US 2015/0380063 A1
(43) Pub. Date: Dec. 31, 2015

(54) SEMICONDUCTOR ARRANGEMENT AND METHODS OF USE

(71) Applicant: Taiwan Semiconductor Manufacturing Company Limited, Hsin-Chu (TW)

(72) Inventors: Chih-Yang Chang, Yuanlin Township (TW); Wen-Ting Chu, Kaohsiung City (TW)

(21) Appl. No.: 14/318,673

(22) Filed: Jun. 29, 2014

(51) Int. Cl. G11C 5/06; G11C 13/00

(52) U.S. Cl. CPC G11C 5/06; G11C 13/0069; G11C 13/0097

(57) ABSTRACT

A semiconductor arrangement and method of use are provided. A semiconductor arrangement includes a resistance random access memory (RRAM) component including a source line electrically coupled to a first active area. The source line of the RRAM comprises a first metal line in parallel with a second metal line, where both the first metal line and the second metal line are electrically coupled to the first active area. The RRAM component also includes a resistor electrically coupled to a second active area. A positive bias is applied to a selected RRAM component during at least one of a set operation or reset operation while a negative bias is concurrently applied to a non-selected RRAM component of the semiconductor arrangement.

### BACKGROUND

Resistance random access memory (RRAM) allows data to be stored using a resistor. A RRAM component is configured to store a bit of data written to the RRAM component. A read operation is performed on the RRAM component to read the stored bit of data from the RRAM component.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is an illustration of a cross sectional view of a semiconductor arrangement at a stage of fabrication, in accordance with some embodiments.

FIG. 2 is an illustration of a cross sectional view of a semiconductor arrangement at a stage of fabrication, in accordance with some embodiments.

FIG. 3 is an illustration of a cross sectional view of a semiconductor arrangement at a stage of fabrication, in accordance with some embodiments.

FIG. 4 is an illustration of a cross sectional view of a semiconductor arrangement at a stage of fabrication, in accordance with some embodiments.

FIG. 5 is an illustration of a cross sectional view of a semiconductor arrangement at a stage of fabrication, in accordance with some embodiments.

FIG. 6 is an illustration of a top down view of a semiconductor arrangement at a stage of fabrication, in accordance with some embodiments.

FIG. 7 is an illustration of a table with values for resistance random access memory (RRAM) operations, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

One or more techniques for forming a semiconductor arrangement and resulting structures formed thereby are provided herein. Some embodiments of the present disclosure have one or a combination of the following features and/or advantages.

According to some embodiments, a semiconductor arrangement comprises a resistance random access memory (RRAM) component. In some embodiments, a source line of the RRAM component comprises a first metal line electrically coupled to a first active area. In some embodiments, the first active area is in a substrate. In some embodiments, the source line of the RRAM component comprises a second metal line electrically coupled to the first active area. In some embodiments, the second metal line is in parallel with the first metal line. In some embodiments, the first metal line has a first length and the second metal line has a second length. In some embodiments, the first length is substantially equal to the second length. In some embodiments, a resistor of the RRAM component is electrically coupled to a second active area in the substrate. In some embodiments, the first active area comprises at least one of a first conductivity type or a second conductivity type. In some embodiments, the second active area comprises at least one of the first conductivity type or the second conductivity type. In some embodiments, when the first active area comprises the first conductivity type the second active area comprises the second conductivity type. In some embodiments, when the first active area comprises the second conductivity type the second active area comprises the first conductivity type. In some embodiments, the resistor is electrically coupled to a bit line.

According to some embodiments, a gate is on the substrate between the first active area and the second active area. In some embodiments, the gate is electrically coupled to a word line. In some embodiments, the source line comprising the first metal line and the second metal line in parallel reduces source line loading by between about 42% to about 50% as compared to a source line that does not comprise a first metal line and a second metal line in parallel, such as where the source line comprises a single metal line that bears the entire load of the source line. In some embodiments, reducing source line loading inhibits overloading, where overloading causes a less than optimal power transfer.

According to some embodiments, a method of using the semiconductor arrangement comprises applying a positive bias to the gate of the RRAM component. In some embodiments, the positive bias is applied during at least one of a set operation or reset operation. In some embodiments, applying the positive bias comprises applying between about 0.5V to about 4V. In some embodiments, the gate of the RRAM component is electrically coupled to a word line. In some embodiments, the RRAM component is a selected component. In some embodiments, the selected component is a component that is being set, reset, read from, or written to.

According to some embodiments, a negative bias is applied to a first gate of a second RRAM component. In some embodiments, applying the negative bias comprises applying about −1.0V to −0.1V. In some embodiments, the negative bias is applied while applying the positive bias. In some embodiments, the second RRAM component is a non-selected component. In some embodiments, the non-selected component is a component that is not the selected component. In some embodiments, the first active area of the RRAM component and a first active area of the second RRAM component are electrically coupled to a source line. In some embodiments, the source line comprises the first metal line in parallel with the second metal line. In some embodiments, the first metal line and the second metal line are electrically coupled to the first active area of the RRAM component. In some embodiments, the second active area of the RRAM component and a second active area of the second RRAM component are electrically coupled to a bit line. In some embodiments, the application of the negative bias to the gate of the unselected or non-selected component concurrently with the application of the positive bias to the gate of the selected component reduces disturb issues, such as experienced by the non-selected component, as compared to when a negative bias is not applied to the gate of the non-selected component while the positive bias is concurrently applied to the gate of the selected component.

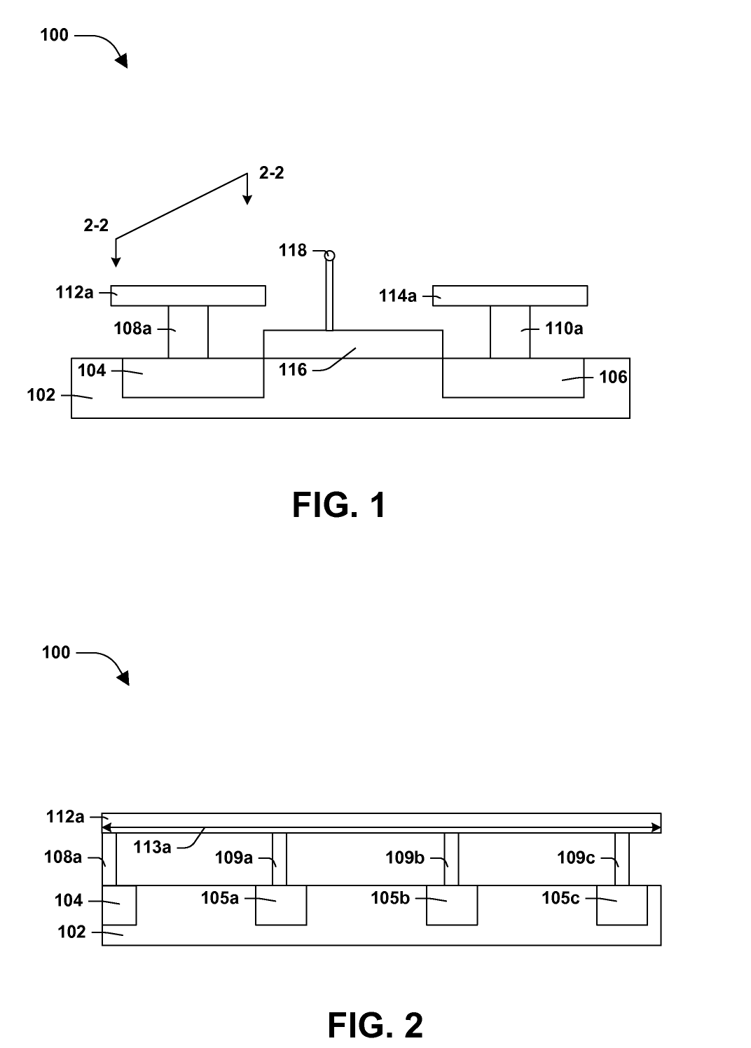

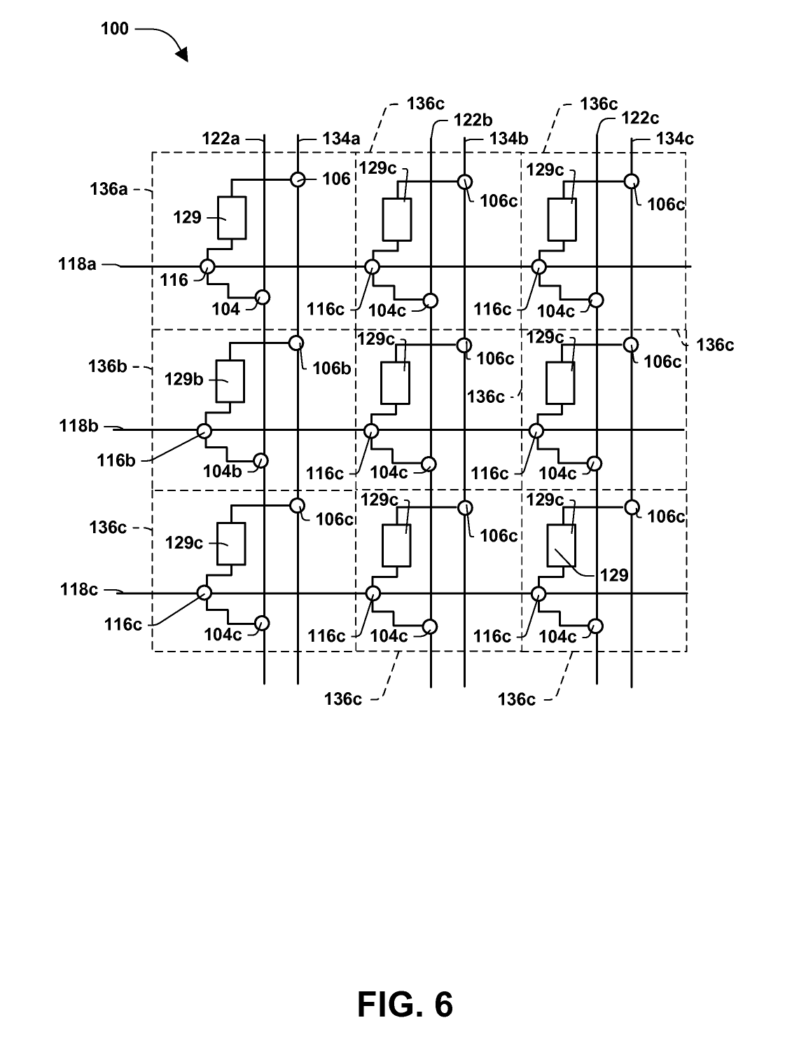

FIGS. 1-5 are cross sectional views of a semiconductor arrangement 100 and FIG. 6 is a top down view of the semiconductor arrangement 100, according to some embodiments, at various stages of fabrication. Turning to FIG. 1, the semiconductor arrangement 100 is formed within or upon at least some of a substrate 102, according to some embodiments. In some embodiments, the substrate 102 includes at least one of an epitaxial layer, a silicon-on-insulator (SOI) structure, a wafer, or a die formed from a wafer. In some embodiments, the substrate 102 comprises at least one of silicon, carbon, etc. In some embodiments, a first active area 104 is in the substrate 102. In some embodiments, the first active area 104 comprises at least one of a first conductivity type or a second conductivity type. In some embodiments, a second active area 106 is in the substrate 102. In some embodiments, the second active area 106 comprises at least of the first conductivity type or the second conductivity type. In some embodiments, the first conductivity type is at least one of n-type or p-type. In some embodiments, the second conductivity type comprises n-type when the first conductivity type comprises p-type and the second conductivity type comprises p-type when the first conductivity type comprises n-type. In some embodiments, a gate 116 is between the first active area 104 and the second active area 106. In some embodiments, the gate 116 is over the substrate 102. In some embodiments, the gate 116 comprises a gate electrode over a gate dielectric. In some embodiments, the gate dielectric is in contact with the substrate 102. In some embodiments, a word line 118 is electrically coupled to the gate 116.

According to some embodiments, a first contact 108a is formed over and electrically coupled to the first active area 104. In some embodiments, a second contact 110a is formed over and electrically coupled to the second active area 106. In some embodiments, at least one of the first contact 108a or the second contact 110a comprises a conductive material, such as metal, metalloid, etc. In some embodiments, a first metal line 112a is electrically coupled to the first active area 104. In some embodiments, the first metal line 112a is formed over and electrically coupled to the first contact 108a. In some embodiments, a first metal line 114a is electrically coupled to the second active area 106. In some embodiments, the first metal line 114a is formed over and electrically coupled to the second contact 110a. In some embodiments, the first metal line 112a and the first metal line 114a are formed from the same layer.

Turning to FIG. 2, a cross-sectional view of the semiconductor arrangement 100 taken along line 2-2 of FIG. 1 is illustrated, according to some embodiments. In some embodiments, a third active area 105a is adjacent the first active area 104 in the substrate 102. In some embodiments, at least one of a fifth active area 105b or a seventh active area 105c is adjacent the first active area 104 in the substrate 102. In some embodiments, the third active area 105a is at least one of adjacent the gate 116, as illustrate in FIG. 1, or a second gate (not shown). In some embodiments, a fourth active area (not shown) is opposite the third active area 105a, such that at least one of the gate 116 or the second gate is between the third active area 105a and the fourth active area. In some embodiments, the fifth active area 105b is at least one of adjacent the gate 116 or a third gate (not shown). In some embodiments, a sixth active area (not shown) is opposite the fifth active area 105b, such that at least one of the gate 116 or the third gate is between the fifth active area 105b and the sixth active area. In some embodiments, the seventh active area 105c is at least one of adjacent the gate 116 or a fourth gate (not shown). In some embodiments, an eighth active area (not shown) is opposite the seventh active area 105c, such that at least one of the gate 116 or the fourth gate is between the seventh active area 105c and the eighth active area. In some embodiments, one or more additional gates and one or more additional active areas are contemplated.

According to some embodiments, a third contact 109a is formed over and electrically coupled to the third active area 105a. In some embodiments, a fifth contact 109b is formed over and electrically coupled to the fifth active area 105b. In some embodiments, a seventh contact 109c is formed over and electrically coupled to the seventh active area 105c. In some embodiments, at least one of the third contact 109a, the fifth contact 109b, or the seventh contact 109c comprises a conductive material, such as metal, metalloid, etc. In some embodiments, one or more additional contacts over and electrically coupled to the one or more additional active areas are contemplated. In some embodiments, the first metal line 112a is formed over and electrically coupled to the first contact 108a. In some embodiments, the first metal line 112a is formed over and electrically coupled to at least one of the third contact 109a, the fifth contact 109b, or the seventh contact 109c. In some embodiments, the first metal line 112a comprises a conductive material, such as metal, metalloid, etc. In some embodiments, the first metal line 112a has a first length 113a.

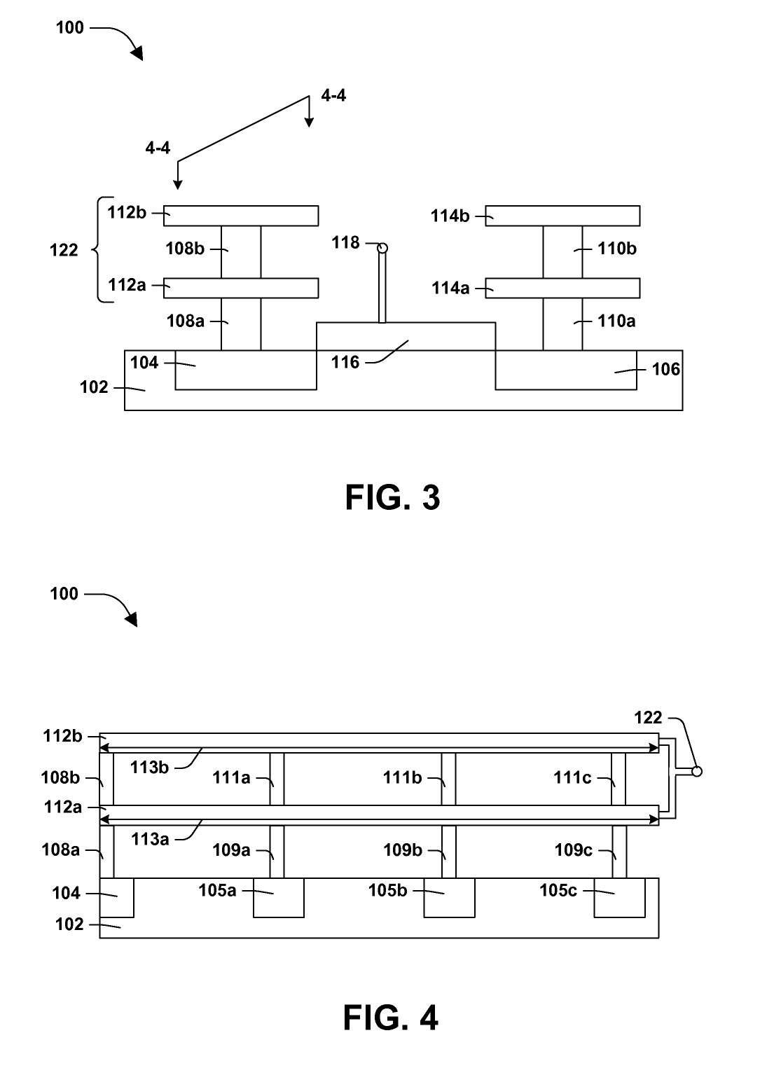

Turning to FIG. 3, a first via 108b is formed over and electrically coupled to the first metal line 112a, according to some embodiments. In some embodiments, a second via 110b is formed over and electrically coupled to the first metal line 114a. In some embodiments, at least one of the first via 108b or the second via 110b comprises a conductive material, such as metal, metalloid, etc. In some embodiments, a second metal line 112b is electrically coupled to the first active area 104. In some embodiments, the second metal line 112b is formed over and electrically coupled to the first via 108b. In some embodiments, a second metal line 114b is electrically coupled to the second active area 106. In some embodiments, the second metal line 114b is formed over and electrically coupled to the second via 110b. In some embodiments, the second metal line 112b comprises a conductive material, such as metal, metalloid, etc. In some embodiments, the second metal line 112b and the second metal line 114b are formed from the same layer.

Turning to FIG. 4, a cross-sectional view of the semiconductor arrangement 100 taken along line 4-4 of FIG. 3 is illustrated, according to some embodiments. In some embodiments, a third via 111a is adjacent the first via 108b and over the third contact 109a and electrically coupled to the first metal line 112a. In some embodiments, at least one of a fourth via 111b or a fifth via 111c is adjacent the first via 108b and over and electrically coupled to the first metal line 112a. In some embodiments, the second metal line 112b is formed over and electrically coupled to the first via 108b. In some embodiments, the second metal line 112b is formed over and electrically coupled to at least one of the third via 111a, the fourth via 111b or the fifth via 111c. In some embodiments, the second metal line 112b has a second length 113b. In some embodiments, the first length 113a is substantially equal to the second length 113b. In some embodiments, one or more additional vias formed over and electrically coupled to the first metal line 112a are contemplated. In some embodiments, the second metal line 112b is formed over and electrically coupled to the one or more additional vias. In some embodiments, the first metal line 112a and the second metal line 112b are in parallel. In some embodiments, the first metal line 112a and the second metal line 112b comprise at least a part of a source line 122.

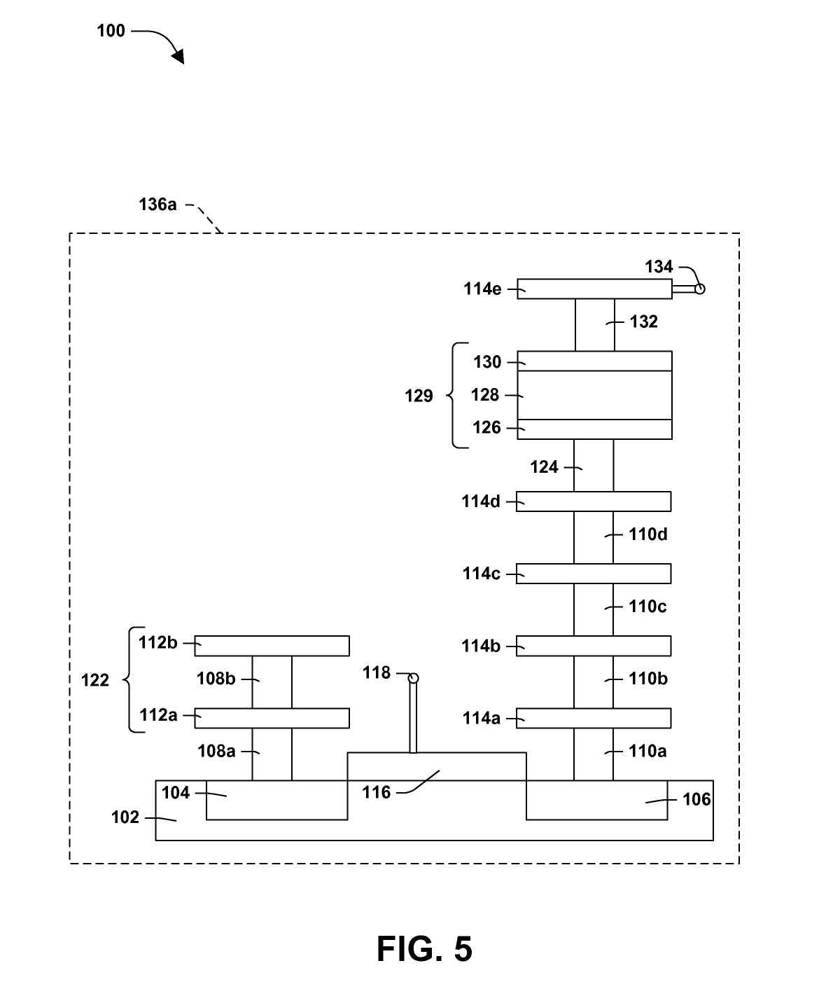

Turning to FIG. 5, at least one of a third metal line 114c electrically coupled to the second active area 106, a fourth metal line 114d electrically coupled to the second active area 106, or a fifth metal line 114e electrically coupled to the second active area 106 is formed over and electrically coupled to the second metal line 114b, according to some embodiments. In some embodiments, a resistor 129 is electrically coupled to at least one of the first metal line 114a, the second metal line 114b, the third metal line 114c, the fourth metal line 114d, or the fifth metal line 114e. In some embodiments, at least one of the first metal line 114a, the second metal line 114b, the third metal line 114c, the fourth metal line 114d, or the fifth metal line 114e comprises a conductive material, such as metal, metalloid, etc.

According to some embodiments, the resistor 129 comprises a top electrode 130, a resistive component 128, and a bottom electrode 126. In some embodiments, the resistive component 128 comprises a low conductive material. In some embodiments, the bottom electrode 126 is electrically coupled to at least one of the first metal line 114a, the second metal line 114b, the third metal line 114c, the fourth metal line 114d, or the fifth metal line 114e by a bottom electrode via 124. In some embodiments, the top electrode 130 is electrically coupled to at least one of the first metal line 114a, the second metal line 114b, the third metal line 114c, the fourth metal line 114d, or the fifth metal line 114e by a top electrode via 132. In some embodiments, the second metal line 114b is electrically coupled to the third metal line 114c by a sixth via 110c. In some embodiments, the third metal line 114c is electrically coupled to the fourth metal line 114d by a seventh via 110d. In some embodiments, at least one of the sixth via 110c, the seventh via 110d, the bottom electrode via 124, or the top electrode via 132 comprises a conductive material such as metal. In some embodiments, the resistor 129 is electrically coupled to a bit line 134, by at least one of the first metal line 114a, the second metal line 114b, the third metal line 114c, the fourth metal line 114d, the fifth metal line 114e, the sixth via 110c, the seventh via 110d, the bottom electrode via 124, or the top electrode via 132. In some embodiments, the first active area 104, the second active area 106, the gate 116, the source line 122, and the resistor 129 comprises a resistance random access memory (RRAM) component 136a.

Turning to FIG. 6, a top down view of the semiconductor arrangement 100 is illustrated, according to some embodiments. In some embodiments, the RRAM component 136a is electrically coupled and adjacent to a second RRAM component 136b. In some embodiments, the first active area 104 of the RRAM component 136a is electrically coupled to a first active area 104b of the second RRAM component 136b by a source line 122a. In some embodiments, the second active area 106 of the RRAM component 136a is electrically coupled to a second active area 106b of the second RRAM component 136b by a bit line 134a. In some embodiments, the gate 116 of the RRAM component 136a is electrically coupled to a word line 118a. In some embodiments, a gate 116b of the second RRAM component 136b is electrically coupled to a second word line 118b.

In some embodiments, one or more additional RRAM components 136c are adjacent at least one of the RRAM component 136a or the second RRAM component 136b. In some embodiments, at least one of the second RRAM component 136b or the one or more additional RRAM components are formed in the same manner and having the same composition as described above with regard to the RRAM component 136a. In some embodiments, the one or more additional RRAM components 136c comprise one of more additional first active areas 104c electrically coupled to one or more one additional source lines, such as 122a, 122b, or 122c, one of more additional second active areas 106c electrically coupled to one or more additional resistors 129c, where the one or more one additional resistors 129c are electrically coupled to one or more additional bit lines, such as 134a, 134b, or 134c. Although in prior illustrations, such as FIGS. 2 and 4, the third active area 105a, the fifth active area 105b, and the seventh active area 105c are depicted, in the present illustration, the third active area 105a, the fifth active area 105b, and the seventh active area 105c are generically referred to as one or more additional first active areas 104c.

According to some embodiments, a method of using the semiconductor arrangement 100 comprises applying a positive bias to the gate 116 of the RRAM component 136a during at least one of a set operation or reset operation where the RRAM component 136a is a selected component. In some embodiments, the selected component is a component that is being set, reset, read from, or written to. In some embodiments, the reset operation comprises applying a first reset bias to the source line 122a such that the first reset bias is applied to the first active area 104 of the RRAM component 136a. In some embodiments, the first reset bias is between about 0.7V to about 2.0V. In some embodiments, the reset operation comprises applying the positive bias to the gate 116 of the RRAM component 136a as a second reset bias. In some embodiments, the second reset bias is between about 1.0V to about 3.0V. In some embodiments, the reset operation comprises applying a bit line reset bias to the bit line 134a. In some embodiments, the bit line reset bias is about 0V. In some embodiments, the second RRAM component 136b comprises a non-selected component. In some embodiments, the non-selected component is a component that is not the selected component. In some embodiments, a negative bias is applied to the first gate 116b of the second RRAM component 136b while applying the positive bias to the gate 116 of the RRAM component 136a. In some embodiments, the negative bias is between about −1.0V to about −0.1V.

According to some embodiments, the set operation comprises applying a first set bias to the source line 122a such that the first set bias is applied to the first active area 104 of the RRAM component 136a. In some embodiments, the first set bias is between about 0V. In some embodiments, the set operation comprises applying the positive bias to the gate 116 of the RRAM component 136a as a second set bias. In some embodiments, the second set bias is between about 0.7 to about 2.0V. In some embodiments, the set operation comprises applying a bit line set bias to the bit line 134a. In some embodiments, the bit line set bias is about between about 0.7 to about 2.0V. In some embodiments, the negative bias is applied to the first gate 116b of the second RRAM component 136b while applying the positive bias to the gate 116 of the RRAM component 136a. In some embodiments, the negative bias is between about −1.0V to about −0.1V.

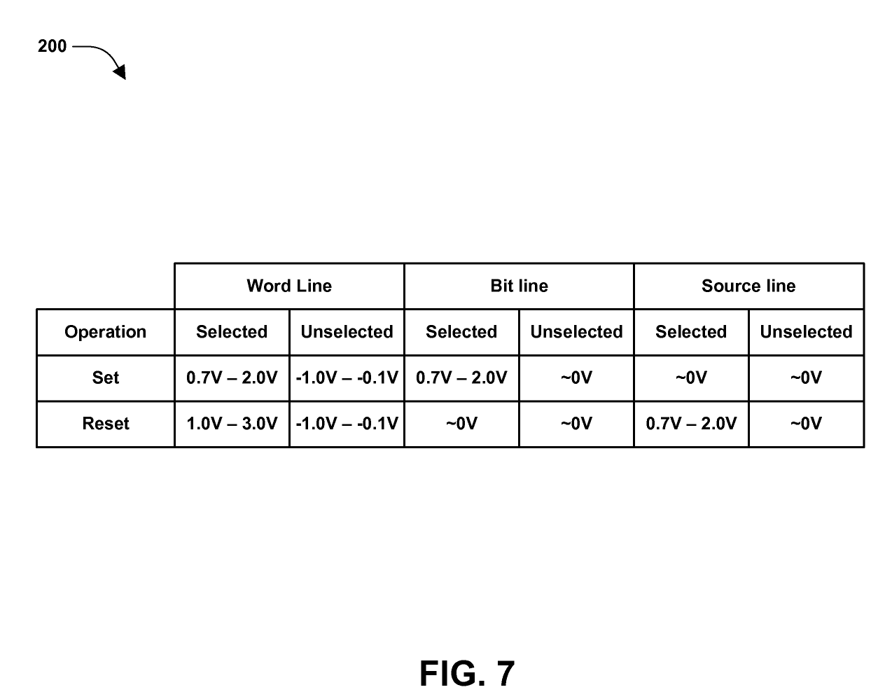

Turning to FIG. 7, a table 200 stating approximate biases or ranges of biases applied to selected RRAM components and non-selected RRAM components is shown, according to some embodiments. In some embodiments, a first column on the left of the page indicates the operation being performed by the application of a bias, either set or reset. In some embodiments, the next column indicates the bias applied to a word line electrically coupled to a gate of a selected RRAM component and the bias applied to a word line electrically coupled to a gate of a non-selected RRAM component. In some embodiments, the next column indicates the bias applied to a bit line electrically coupled to a resistor of a selected RRAM component and the bias applied to a bit line electrically coupled to a resistor of a non-selected RRAM component. In some embodiments, the next and last column indicates the bias applied to a source line electrically coupled to a first active area of a selected RRAM component and the bias applied to a source line electrically coupled to a first active area of a non-selected RRAM component.

According to some embodiments, the source line 122 comprising the first metal line 112a and the second metal line 112b in parallel reduce a source line loading by between about 42% to about 50% as compared to a source line that does not comprise a first metal line and a second metal line in parallel. In some embodiments, reducing source line loading inhibits overloading, where overloading causes a less than optimal power transfer. In some embodiments, the application of the negative bias to the gate of the non-selected component concurrently with the application of the positive bias to the selected component reduces disturb issues as compared to a non-selected component that does not have a negative bias applied thereto.

According to some embodiments, a semiconductor arrangement comprises a resistance random access memory (RRAM) component. The RRAM component comprises a source line comprising a first metal line electrically coupled to a first active area, the first active area in a substrate and a second metal line electrically coupled to the first active area. In some embodiments, the second metal line in parallel with the first metal line. In some embodiments, a resistor is electrically coupled to a second active area in the substrate. In some embodiments, a gate is between the first active area and the second active area.

According to some embodiments, a method of using a semiconductor arrangement comprises applying a positive bias to a gate of a resistance random access memory (RRAM) component on a substrate during at least one of a set operation or reset operation. In some embodiments, the gate is electrically coupled to a word line of the RRAM component. In some embodiments, the RRAM component is a selected component. According to some embodiments, the method of using a semiconductor arrangement comprises applying a negative bias to a first gate of a second RRAM component while applying the positive bias, where the second RRAM component is a non-selected component. In some embodiments, a first active area of the RRAM component and a first active area of the second RRAM component are electrically coupled to a source line. In some embodiments, a second active area of the RRAM component and a second active area of the second RRAM component are electrically coupled to a bit line.

According to some embodiments, a semiconductor arrangement comprises a resistance random access memory (RRAM) component comprising a source line. In some embodiments, the source line comprises a first metal line and a second metal line electrically coupled to a first active area. In some embodiments, the first active area is in a substrate. In some embodiments, a second metal line is electrically coupled to the first active area. In some embodiments, the second metal line is in parallel with the first metal line. In some embodiments, a resistor is electrically coupled to a second active area in the substrate. In some embodiments, the resistor is electrically coupled to a bit line. In some embodiments, a gate is between the first active area and the second active area. In some embodiments, the gate is electrically coupled to a word line.

The foregoing outlines features of several embodiments so that those of ordinary skill in the art may better understand various aspects of the present disclosure. Those of ordinary skill in the art should appreciate that they may readily use the present disclosure as a basis for designing or modifying other processes and structures for carrying out the same purposes and/or achieving the same advantages of various embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

Although the subject matter has been described in language specific to structural features or methodological acts, it is to be understood that the subject matter of the appended claims is not necessarily limited to the specific features or acts described above. Rather, the specific features and acts described above are disclosed as example forms of implementing at least some of the claims.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

It will be appreciated that layers, features, elements, etc. depicted herein are illustrated with particular dimensions relative to one another, such as structural dimensions or orientations, for example, for purposes of simplicity and ease of understanding and that actual dimensions of the same differ substantially from that illustrated herein, in some embodiments. Additionally, a variety of techniques exist for forming the layers, regions, features, elements, etc. mentioned herein, such as at least one of etching techniques, planarization techniques, implanting techniques, doping techniques, spin-on techniques, sputtering techniques, growth techniques, or deposition techniques such as chemical vapor deposition (CVD), for example.

Moreover, “exemplary” is used herein to mean serving as an example, instance, illustration, etc., and not necessarily as advantageous. As used in this application, “or” is intended to mean an inclusive “or” rather than an exclusive “or”. In addition, “a” and “an” as used in this application and the appended claims are generally be construed to mean “one or more” unless specified otherwise or clear from context to be directed to a singular form. Also, at least one of A and B and/or the like generally means A or B or both A and B. Furthermore, to the extent that “includes”, “having”, “has”, “with”, or variants thereof are used, such terms are intended to be inclusive in a manner similar to the term “comprising”. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others of ordinary skill in the art based upon a reading and understanding of this specification and the annexed drawings. The disclosure comprises all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

1. A semiconductor arrangement comprising:
a resistance random access memory (RRAM) component comprising:
a source line comprising:
a first metal line electrically coupled to a first active area, the first active area in a substrate;
a second metal line electrically coupled to the first active area, the second metal line in parallel with the first metal line;
a resistor electrically coupled to a second active area in the substrate; and
a gate between the first active area and the second active area.

2. The semiconductor arrangement of claim 1, the first active area, the second active area and the gate comprising at least one of complementary metal oxide semiconductor (CMOS), an n-type metal oxide semiconductor (NMOS), or a p-type metal oxide semiconductor (PMOS).

3. The semiconductor arrangement of claim 1, comprising at least one of a first metal line electrically coupled to the second active area, a second metal line electrically coupled to the second active area, a third metal line electrically coupled to the second active area, a fourth metal line electrically coupled to the second active area, or a fifth metal line electrically coupled to the second active area electrically coupling the second active area to the resistor.

4. The semiconductor arrangement of claim 1, the resistor electrically coupled to a bit line.

5. The semiconductor arrangement of claim 1, the gate electrically coupled to a word line.

6. The semiconductor arrangement of claim 1, the first metal line having a first length and the second metal line having a second length, the first length substantially equal to the second length.

7. The semiconductor arrangement of claim 1, comprising a third active area adjacent the first active area, the third active area electrically coupled to the first metal line and the second metal line and adjacent at least one of the gate or a second gate.

8. The semiconductor arrangement of claim 7, comprising a fifth active area adjacent at least one of the first active area or the third active area, the fifth active area electrically coupled to the first metal line and the second metal line and adjacent at least one of the gate or a third gate.

9.-14. (canceled)

15. A semiconductor arrangement comprising:
a resistance random access memory (RRAM) component comprising:
a source line comprising:
a first metal line electrically coupled to a first active area, the first active area in a substrate;
a second metal line electrically coupled to the first active area, the second metal line in parallel with the first metal line;
a resistor electrically coupled to a second active area in the substrate, the resistor electrically coupled to a bit line; and
a gate between the first active area and the second active area, the gate electrically coupled to a word line.

16. The semiconductor arrangement of claim 15, the first active area, the second active area and the gate comprising at least one of complementary metal oxide semiconductor (CMOS), an n-type metal oxide semiconductor (NMOS), or a p-type metal oxide semiconductor (PMOS).

17. The semiconductor arrangement of claim 15, comprising at least one of a first metal line electrically coupled to the second active area, a second metal line electrically coupled to the second active area, a third metal line electrically coupled to the second active area, a fourth metal line electrically coupled to the second active area, or a fifth metal line electrically coupled to the second active area electrically coupling the second active area to the resistor.

18. The semiconductor arrangement of claim 15, the first metal line having a first length and the second metal line having a second length, the first length substantially equal to the second length.

19. The semiconductor arrangement of claim 15, comprising a third active area adjacent the first active area, the third active area electrically coupled to the first metal line and the second metal line and adjacent at least one of the gate or a second gate.

20. The semiconductor arrangement of claim 19, comprising a fifth active area adjacent at least one of the first active area or the third active area, the fifth active area electrically coupled to the first metal line and the second metal line and adjacent at least one of the gate or a third gate.

21. A semiconductor arrangement comprising:
a resistance random access memory (RRAM) component comprising:
a source line comprising:
a first metal line, and
a second metal line, the first metal line and the second metal line electrically coupled in parallel between a source line and a first active area; and
a resistor electrically coupled to a second active area, the second active area different than the first active area.

22. The semiconductor arrangement of claim 21, the RRAM component comprising:
a bit line, the resistor electrically coupled between the bit line and the second active area.

23. The semiconductor arrangement of claim 21, the RRAM component comprising:
a gate disposed between the first active area and the second active area.

24. The semiconductor arrangement of claim 23, the gate electrically coupled to a word line.

25. The semiconductor arrangement of claim 21, the RRAM component comprising:
a third active area, the first metal line and the second metal line electrically coupled in parallel between the source line and a third active area.

26. The semiconductor arrangement of claim 21, the first active area and the second active area being part of a metal oxide semiconductor (MOS).
